(19) United States
(12) Patent Application Publication
(10) Pub. No.: US 2026/0052928 A1
(43) Pub. Date: Feb. 19, 2026

(54) METHOD OF MANUFACTURING SEMICONDUCTOR DEVICE

(71) Applicant: Samsung Electronics Co., Ltd., Suwon-si (KR)

(72) Inventor: Jinmo KWON, Suwon-si (KR)

(73) Assignee: Samsung Electronics Co., Ltd., Suwon-si (KR)

(21) Appl. No.: 19/268,035

(22) Filed: Jul. 14, 2025

(30) Foreign Application Priority Data
Aug. 13, 2024 (KR) 10-2024-0108615

(51) Int. Cl. H01L 21/78; H01L 21/268; H01L 21/683; H01L 23/544

(52) U.S. Cl. CPC H01L 21/78; H01L 21/268; H01L 21/6836; H01L 23/544; H01L 2223/54426

(57) ABSTRACT

A method of manufacturing a semiconductor device includes cutting a substrate structure along a scribe lane to separate a plurality of semiconductor devices from the substrate structure. The substrate structure includes a plurality of device regions and the scribe lane separates the plurality of device regions. Each of the plurality of device regions includes a first side and a second side opposite the first side. Each of the plurality of device regions includes bonding pads arranged along the first side, and bonding pads are absent on a region adjacent to the second side. The plurality of device regions are arranged such that the first side and the second side of adjacent device regions face each other and the scribe lane is therebetween in the substrate structure. The substrate structure further includes metal patterns arranged closer to the second side than to the first side in the scribe lane.

### CROSS-REFERENCE TO RELATED APPLICATIONS

This application claims priority under 35 U.S.C. § 119 to Korean Patent Application No. 10-2024-0108615 filed on Aug. 13, 2024, in the Korean Intellectual Property Office, the disclosure of which is incorporated herein by reference in its entirety.

### BACKGROUND

Example embodiments of the inventive concepts relate to a method of manufacturing a semiconductor device.

A cutting process refers to a process of cutting a wafer to separate semiconductor chips or dies after a wafer manufacturing process and prior to an assembly process in a semiconductor manufacturing process. A wafer on which a semiconductor device is formed may be cut along a scribe lane. For example, semiconductor chips or dies may be obtained by cutting the wafer using a dicing saw or a laser beam.

### SUMMARY

Example embodiments of the inventive concepts provide a method of manufacturing a semiconductor device that reduces defects caused by cracks or the like occurring during a wafer cutting process.

According to some example embodiments of the inventive concepts, a method of manufacturing a semiconductor device includes irradiating a laser along a center line of a scribe lane of a substrate structure. The substrate structure includes a plurality of device regions that are separated by the scribe lane and a plurality of metal patterns arranged on the scribe lane, the substrate structure includes a semiconductor substrate having an upper surface on which circuit devices are formed, and an interconnection structure disposed on the upper surface of the semiconductor substrate and electrically connected to the circuit devices, and irradiating the laser along the center line of the scribe lane forms modified portions in the semiconductor substrate. The method further includes polishing a lower surface of the semiconductor substrate to reduce a thickness of the substrate structure, and separating the substrate structure into the plurality of device regions to form a plurality of semiconductor devices. Each device region of the plurality of device regions includes bonding pads arranged along a first side of the device region, in each device region of the plurality of device regions, bonding pads are absent on a region adjacent to a second side of the device region opposite to the first side, the plurality of device regions are arranged such that the first and second sides each device region face each other and the scribe lane is therebetween, and the plurality of metal patterns are closer to the second side than to the first side in the scribe lane.

According to some example embodiments of the inventive concepts, a method of manufacturing a semiconductor device includes irradiating a laser along center lines of a plurality of first scribe lanes and a plurality of second scribe lanes of a substrate structure.

The substrate structure includes the plurality of first scribe lanes extending in a first direction and spaced apart from each other in a second direction that interests the first direction, the plurality of second scribe lanes extending in the second direction and spaced apart from each other in the first direction, a plurality of device regions defined by the plurality of first scribe lanes and the plurality of second scribe lanes, a semiconductor substrate having an upper surface including circuit devices, and an interconnection structure on the upper surface of the semiconductor substrate and electrically connected to the circuit devices, and irradiating the laser along the center lines of the plurality of first and second scribe lanes forms modified portions in the semiconductor substrate. The method further includes polishing a lower surface of the semiconductor substrate to reduce a thickness of the substrate structure; and separating the substrate structure into the plurality of device regions to form a plurality of semiconductor devices. Each device region of the plurality of device regions has a first side and a second side located opposite to each other in the second direction, and in the substrate structure, the plurality of device regions are arranged such that the first side and the second side face each other and a scribe lane of the plurality of first scribe lanes is therebetween, each device region of the plurality of device regions includes first bonding pads arranged along the first side, in each device region of the plurality of device regions, bonding pads are absent on a region adjacent to the second side, and the substrate structure further includes first metal patterns offset from a center line of each of the plurality of first scribe lanes, the first metal patterns being closer to the second side than the first side.

According to some example embodiments of the inventive concepts, a method of manufacturing a semiconductor device includes cutting a substrate structure along a scribe lane to separate a plurality of semiconductor devices from the substrate structure, the substrate structure including a plurality of device regions and the scribe lane separating the plurality of device regions. Each of the plurality of device regions includes a first side and a second side opposite the first side. Each of the plurality of device regions includes bonding pads arranged along the first side, and bonding pad are absent on a region adjacent to the second side. The plurality of device regions are arranged such that the first side and the second side of adjacent device regions face each other and the scribe lane is therebetween, and the substrate structure further includes metal patterns arranged closer to the second side than to the first side in the scribe lane.

### BRIEF DESCRIPTION OF DRAWINGS

These and other aspects, features, and advantages of some example embodiments of the inventive concepts will be more clearly understood from the following detailed description, taken in conjunction with the accompanying drawings.

FIG. 1 is a perspective view illustrating a substrate structure for a plurality of semiconductor devices.

FIG. 2 is a partially enlarged plan view illustrating portion A of FIG. 1.

FIG. 3 is a partially enlarged view illustrating portion B of FIG. 2.

FIG. 4 is a side cross-sectional view taken along line I-I′ of FIG. 3.

FIG. 5 is a perspective view illustrating a semiconductor device according to some example embodiments of the inventive concepts.

FIG. 6 is a side cross-sectional view illustrating a semiconductor package including the semiconductor devices of FIG. 5, according to some example embodiments.

FIG. 7 is a perspective view illustrating a semiconductor device according to some example embodiments of inventive concepts.

FIGS. 8A, 8B, 8C, and 8D are side cross-sectional views illustrating processes in a method of manufacturing a semiconductor device, according to some example embodiments of inventive concepts.

FIGS. 9A and 9B are perspective views illustrating processes of the method of manufacturing a semiconductor device in FIGS. 8A, 8B, 8C, and 8D, according to some example embodiments of inventive concepts.

FIG. 10 is a plan view illustrating a portion of a substrate structure for a plurality of semiconductor devices.

FIG. 11 is a partially enlarged view illustrating portion B1 of FIG. 10.

FIGS. 12A and 12B are cross-sectional side views of a wafer portion of FIG. 11 taken along lines I1-I1′ and I2-I2′.

### DETAILED DESCRIPTION

Hereinafter, some example embodiments of the inventive concepts will be described in detail with reference to the accompanying drawings.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

While the term “same,” “equal” or “identical” may be used in description of some example embodiments, it should be understood that some imprecisions may exist. Thus, when one element, value, and/or property is referred to as being the same as another element, value, and/or property, it should be understood that an element, value, and/or property is the same as another element, value, and/or property within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, an element that is described to be “spaced apart” from another element, in general and/or in a particular direction (e.g., vertically spaced apart, laterally spaced apart, etc.) and/or described to be “separated from” the other element, may be understood to be isolated from direct contact with the other element, in general and/or in the particular direction (e.g., isolated from direct contact with the other element in a vertical direction, isolated from direct contact with the other element in a lateral or horizontal direction, etc.). Similarly, elements that are described to be “spaced apart” from each other, in general and/or in a particular direction (e.g., vertically spaced apart, laterally spaced apart, etc.) and/or are described to be “separated” from each other, may be understood to be isolated from direct contact with each other, in general and/or in the particular direction (e.g., isolated from direct contact with each other in a vertical direction, isolated from direct contact with each other in a lateral or horizontal direction, etc.). Similarly, a structure described herein to be between two other structures to separate the two other structures from each other may be understood to be configured to isolate the two other structures from direct contact with each other.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

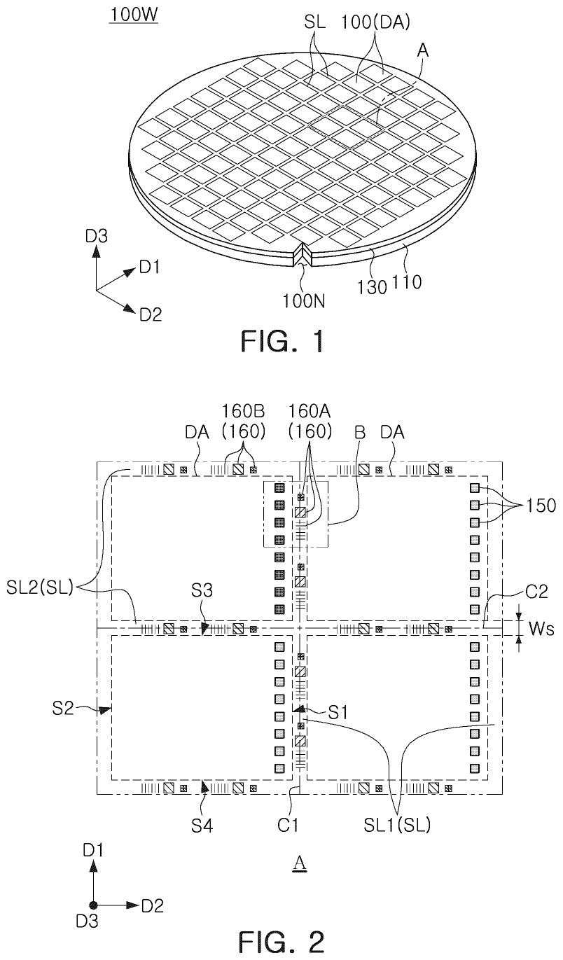

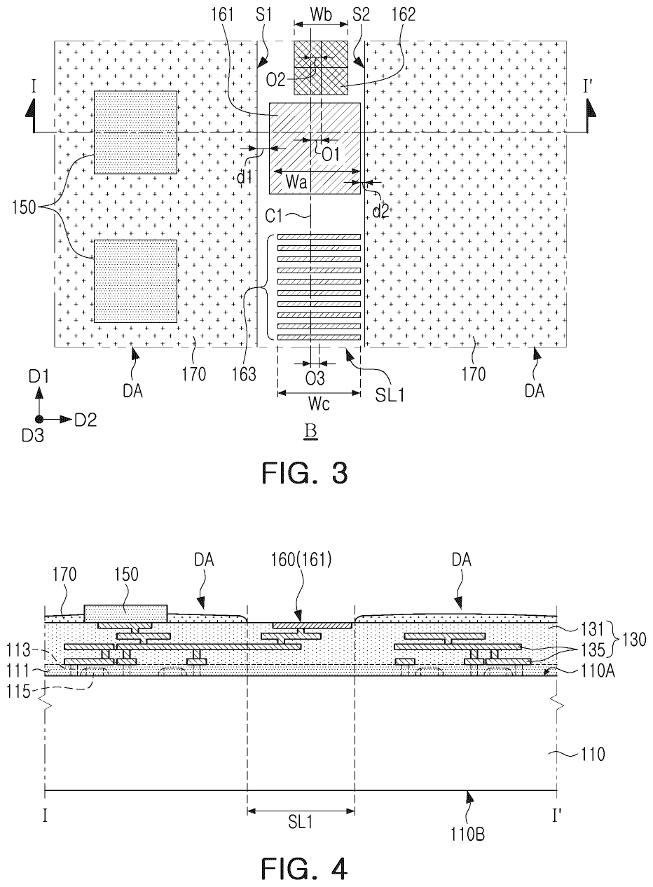

FIG. 1 is a perspective view illustrating a substrate structure for a plurality of semiconductor devices. FIG. 2 is a partially enlarged plan view illustrating portion A of FIG. 1. FIG. 3 is a partially enlarged view illustrating portion B of FIG. 2. FIG. 4 is a side cross-sectional view of a portion of FIG. 3 taken along line I-I′.

Referring to FIGS. 1 and 2, a substrate structure 100W, according to some example embodiments, may include a plurality of device regions DA and scribe lanes SL dividing the plurality of device regions DA in plan view.

According to some example embodiments, the plurality of device regions DA may be arranged in a first direction D1 and a second direction D2 intersecting each other. The scribe lanes SL may include a plurality of first scribe lanes SL1 extending in the first direction D1 and spaced apart from each other in the second direction D2 and a plurality of second scribe lanes SL2 extending in the second direction D2 and spaced apart from each other in the first direction D1. The substrate structure 100W may include (or otherwise define) a notch 100N that may be used as a reference point for aligning a region of the edge of the substrate structure 100W.

Referring to FIG. 4 together with FIGS. 1 to 3, the substrate structure 100W may include a semiconductor substrate 110 having an upper surface 110A on which circuit devices 115 may be implemented and an interconnection structure 130 electrically connected to the circuit devices 115 on the upper surface 110A of the semiconductor substrate 110.

The semiconductor substrate 110 may be a circular semiconductor wafer. For example, the semiconductor substrate 110 may be a silicon wafer. However, the semiconductor substrate 110 is not limited thereto and may include germanium, or the semiconductor substrate 110 may be a compound semiconductor wafer, including, for example, silicon carbide (SiC), gallium arsenide (GaAs), indium arsenide (InAs), and indium phosphide (InP). Alternatively, the semiconductor substrate 110 may have a silicon on insulator (SOI) structure.

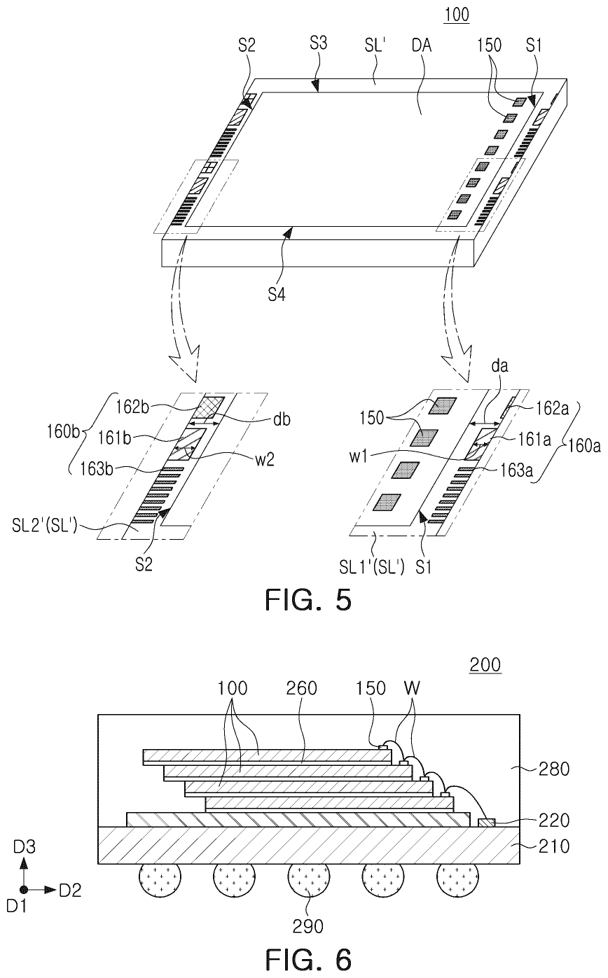

The upper surface 110A of the semiconductor substrate 110 may be referred to as an active surface, and a lower surface 110B of the semiconductor substrate 110 may be referred to as an inactive surface. The upper surface of the semiconductor substrate 110 may be or include an active region, such as a well doped with impurities or a structure doped with impurities. The active region may be defined by an isolation structure, such as a shallow trench isolation (STI) structure, formed on the upper surface 110A of the semiconductor substrate 110. The circuit devices 115 may be formed in the active region of the semiconductor substrate to configure (or form) an integrated circuit and cell structure (e.g., a memory cell) required for a desired semiconductor device (100 of FIG. 5). In some example embodiments, the semiconductor device may include dynamic random access memory (DRAM). Example embodiments of the inventive concepts are not limited thereto, and the semiconductor device may include a volatile memory device or non-volatile memory device. For example, the volatile memory devices may include memory devices, such as DRAM, static RAM (SRAM), thyristor RAM (TRAM), zero capacitor RAM (ZRAM), or twin transistor RAM (TTRAM). The non-volatile memory devices may include, for example, flash memory, magnetic RAM (MRAM), spin-transfer torque MRAM (STT-MRAM), ferroelectric RAM (FRAM), phase change RAM (PRAM), resistive RAM (RRAM), nanotube RRAM, polymer RAM, nano floating gate memory, holographic memory, molecular electronics memory, or insulator resistance change memory.

In some example embodiments, the semiconductor device 100 may include a logic device. The logic device may be implemented as, for example, a microprocessor, a graphics processor, a signal processor, a network processor, an audio codec, a video codec, an application processor, or a system-on-chip, but example embodiments are not limited thereto.

As described above, the plurality of device regions DA are regions in which circuit devices 115 that may form an integrated circuit are formed, and the scribe lanes SL are regions in which such circuit devices are not formed. In some example embodiments, dummy elements having a structure similar to that of the circuit devices 115 may be arranged in the scribe lanes SL.

In some example embodiments, an interlayer insulating film 111 may be formed on the upper surface 110A of the semiconductor substrate 110 to cover the circuit devices 115, and the interconnection structure 130 connected to the circuit devices 115 may be formed on the interlayer insulating film 111. The interconnection structure 130 may include a multilayer (e.g., three layers illustrated in FIG. 4) interconnection structure including a plurality of low-κ layers 131 and a plurality of interconnection layers 135. The plurality of interconnection layers 135 may be connected to a contact via 113 that may be connected to the circuit devices 115 through the interlayer insulating film 111. The plurality of interconnection layers 135 may respectively include a metal line on the low-κ layer 131 and a metal via connected to the metal line through the low-κ layer 131. For example, the plurality of interconnection layers 135 may include at least one of copper (Cu), aluminum (Al), nickel (Ni), tungsten W, platinum (Pt), and gold (Au). The interlayer insulating film 111 and the low-κ layer 131 may include, for example, silicon oxide.

Referring to FIGS. 2 to 4, metal patterns 160 may be arranged on the scribe lanes SL. The metal patterns 160 may include a test pad 161, an alignment key pattern 162, and various other alignment patterns 163.

The test pad 161 may also be referred to as a test element group (TEG) and may be a pattern for testing an integrated circuit formed of the circuit devices 115. As shown in FIG. 4, the test pad 161 may be disposed on the interconnection structure 130 region within the scribe lane SL and may be connected to the circuit devices 115 through the interconnection layer 135. Before the cutting process, the test pad 161 may be used as a probing pad to evaluate the performance and defects of the integrated circuit including the circuit devices 115.

The alignment key pattern 162 may be an alignment key for a photolithography process. The various other alignment patterns 163 may include alignment patterns, such as an overlay key, a back end of site (BEOS), an oxide site (OS), and an optical CD (OCD).

The overlay key may be a pattern for measuring an alignment state of a layer formed in a previous process and a layer formed in a current process. The BEOS may be a pattern for measuring a thickness of the uppermost layer after a CMP process and may be a pattern for measuring a thickness of the outermost layer similar to the BEOS. The OCD may be a pattern for measuring a thickness of a CD or an inner side by an optical method. Accordingly, various metal patterns 160 may be arranged on the scribe lane SL.

Referring to FIGS. 2 and 3, the test pad 161, alignment key patterns 162, and other alignment patterns 163 are illustrated as being arranged in the region of the interconnection structure 130 within the scribe lane SL, but in some example embodiments, one or more of the alignment key patterns 162 and the other alignment patterns 163 may be arranged on any low-κ layer 131 within the interconnection structure 130 or on the upper surface 110A of the semiconductor substrate 110.

The plurality of device regions DA may be provided as a plurality of semiconductor devices (‘100’ in FIG. 4), respectively. In some example embodiments, each of the plurality of device regions DA may be defined as a square shape having four sides (S1 to S4) in plan view. As illustrated in FIG. 2, each of the plurality of device regions may include a first side S1 and a second side S2 located opposite to each other in the second direction D2 and a third side S3 and a fourth side S4 located opposite to each other in the first direction D1.

Each of the plurality of device regions DA may include bonding pads 150 arranged asymmetrically. In some example embodiments, the bonding pads 150 may be arranged in a region adjacent to the first side S1 of each of the plurality of device regions DA. Referring to FIG. 2, the bonding pads 150 in each of the plurality of device regions DA may be arranged to be spaced apart from each other in the first direction D1 along the first side S1. The bonding pads may not be arranged on other sides in each of the plurality of device regions DA. The region adjacent to the third and fourth sides S3 and S4 as well as the second side S2 may be provided as a region in which no bonding pad is formed.

As described above, referring to FIGS. 2 to 4, each of the plurality of device regions DA includes bonding pads 150 arranged along the first side S1, but may have a pad-free region in which no bonding pads are arranged in a region adjacent to the second side S2 located opposite thereto.

In the substrate structure 100W, the adjacent device regions DA may be arranged such that the first side S1 and the second side S2 face each other with the first scribe lane SL interposed therebetween. In the substrate structure 100W, the pad-free region on the second side S2 may be disposed to face at least the region in which the bonding pads 150 on the first side S1 are arranged, with the first scribe lane SL1 interposed therebetween.

The metal patterns 160, according to some example embodiments, may include first metal patterns 160A arranged on the first scribe lane SL1 and second metal patterns 160B arranged on the second scribe lane SL2.

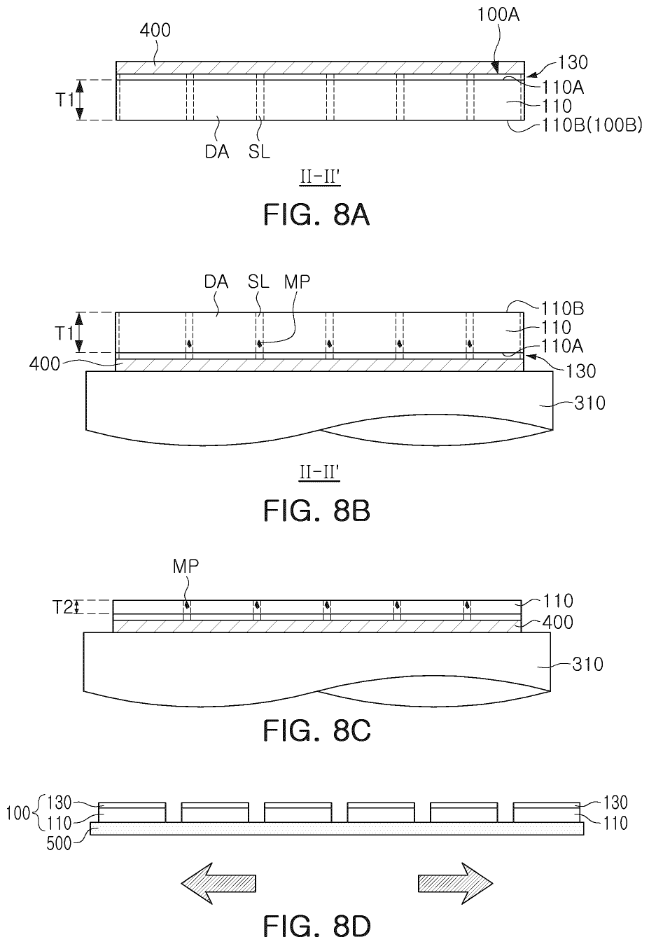

Referring to FIG. 3, the first metal patterns 160A on the first scribe lane SL1 may be disposed to be closer to the second side S2 than to the first side S1. The first metal patterns 160A may be arranged such that 10% or more of the widths Wa, Wb, and Wc thereof are offset from a first center line C1 of the first scribe lane SL1 and are closer to the second side S2. By this offset arrangement, the first metal patterns 160A may be arranged such that a distance (e.g., d1) from the first side S1 is greater than a distance (e.g., d2) from the second side S2. As the offset distances O1, O2, and O3 increase, a deviation between the distance of the first metal patterns 160A from the first side S1 and the distance thereof from the second side S2 may increase. Here, the ‘first center line C1’ may be a virtual or imaginary line extending in the first direction D1 along the center of the width direction of the first scribe lane SL1. The first center line C1 of the first scribe lane SL1 may be or otherwise define a region in which a laser beam is irradiated, and may substantially overlap a cutting line in which separation occurs in a cutting process (see FIG. 8D).

In some example embodiments, since a crack occurring during a cutting process may propagate laterally from a vicinity of the first metal patterns 160A, the possibility of the crack propagating to the bonding pad 150 may be reduced by offsetting the first metal patterns 160A from the first center line C1 so that the first metal patterns 160A are relatively closer to the pad-free region. Since the test pad 161 of the first metal patterns 160A is connected to the interconnection layer 135 extending to the device region DA, the crack may propagate along the interconnection layer 135. Therefore, the offset arrangement of the test pad 161, according to some example embodiments, may reduce, limit, or minimize defects in the bonding pad 150 due to peeling of, for example, the interconnection structure 130, that may occur at or adjacent the bonding pad 150 because of the crack.

In order to reduce defects in the bonding pad 150, a difference (d1−d2) in the distance from the adjacent sides S1 and S2 may be at least 5 μm (or about 5 μm). In some example embodiments, a width Ws of the first scribe lane SL1 and/or second scribe lane SL2 may be 40 μm (or about 40 μm) to 100 μm (or about 100 μm), and the widths Wa, Wb, and Wc of the first metal patterns 160A may be 20 μm (or about 20 μm) to 60 μm (or about 60 μm), although the widths may vary depending on application and/or design.

As illustrated in FIG. 2, each of the plurality of device regions DA has the third side S3 and the fourth side S4 located opposite to each other in the first direction D1, and in the substrate structure 100W, the plurality of device regions DA may be arranged such that the third side S3 and the fourth side S4 face each other with the second scribe lanes SL2 interposed therebetween.

In some example embodiments, similarly to the first metal patterns 160A, the second metal patterns 160B may be arranged in the second scribe lane SL2. As illustrated in FIG. 2, the first and second metal patterns 160A and 160B are illustrated as arranged in the same order for sake of illustration. However, example embodiments of the inventive concepts are not limited thereto, and in some example embodiments, the combinations, positions, and/or orders of the first and second metal patterns 160A and 160B in the first and second scribe lanes SL1 and SL2 may be varied depending on application and/or design.

In some example embodiments, each of the plurality of device regions DA may have a pad-free region in which no bonding pads 150 are arranged in a region adjacent to each of the third side S3 and the fourth side S4. In some example embodiments, the second metal patterns 160B may be arranged so that the centers thereof are located on a second center line C2. However, example embodiments of the inventive concepts are not limited thereto and the second metal patterns 160B may be offset from the center line C2, for example, in a manner similar to the first metal patterns 160A. Here, the ‘second center line C2’ may be a virtual or imaginary line extending in the second direction D2 along the center of the second scribe lane SL2 in the width direction. Similar to the first center line C1 described above, the second center line C2 of the second scribe lane SL2 may be or otherwise define a region that may be irradiated with a laser beam and may substantially overlap a cutting line in which separation occurs in the cutting process (see FIG. 8D).

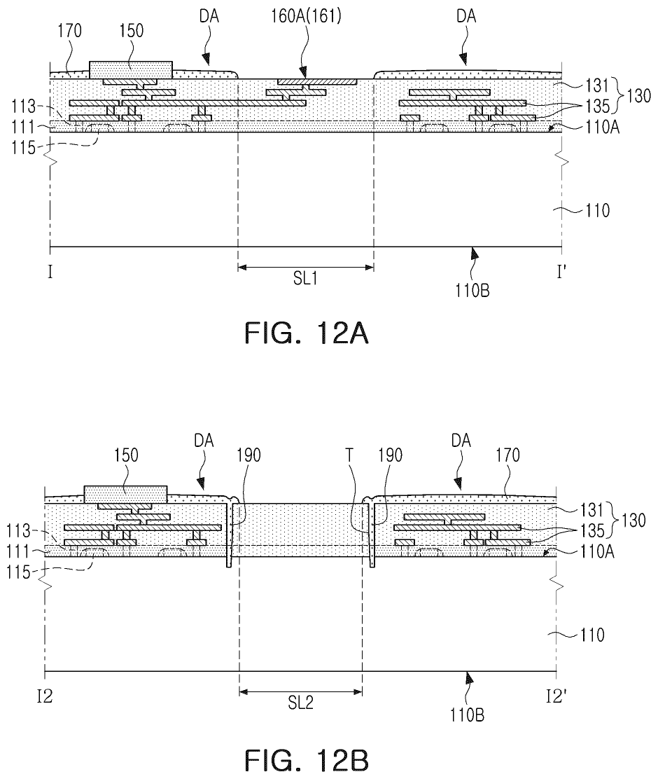

A passivation layer 170 may be formed on the interconnection structure 130 of the plurality of device regions DA so that the bonding pads 150 are exposed. In some example embodiments, the passivation layer 170 may extend to a portion of the scribe lane SL (see FIG. 12B).

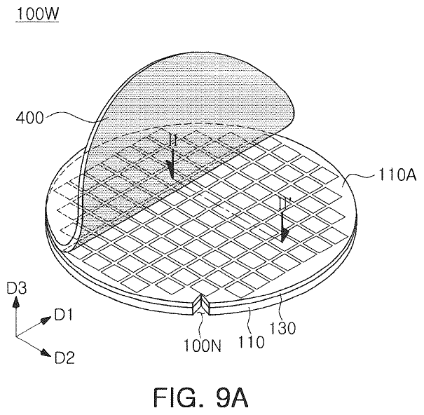

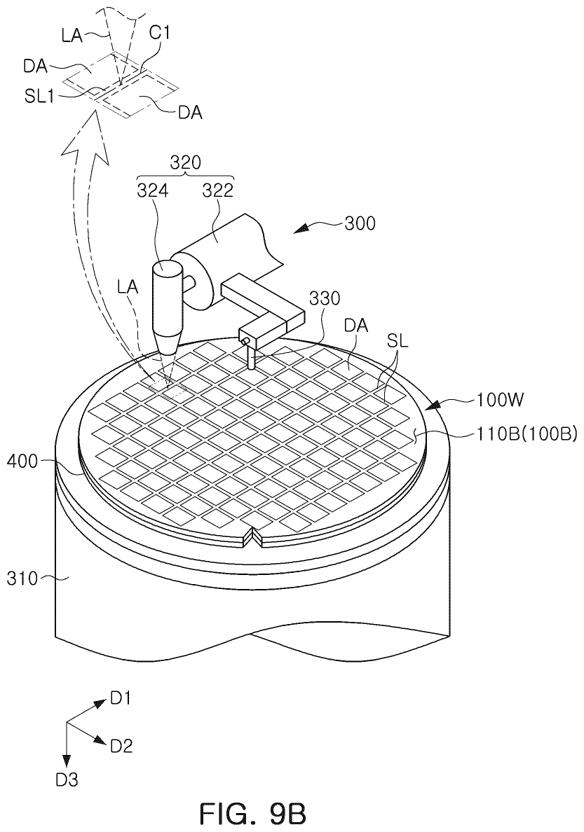

The substrate structure 100W described above with reference to FIGS. 1 to 4 may be separated into a plurality of semiconductor devices respectively having the device region DA, by a series of cutting processes (e.g., see FIGS. 8A to 8D and FIGS. 9A and 9B), and as described above, by introducing an offset arrangement of the metal patterns 160, a defect of the bonding pad 150 may be mitigated or reduced in the cutting process. A side structure of the plurality of semiconductor devices 100 due to the offset arrangement of the metal patterns 160 obtained after the cutting process is described with reference to FIG. 5.

FIG. 5 is a perspective view illustrating a semiconductor device according to some example embodiments of the inventive concepts. In some example embodiments, the semiconductor device 100 illustrated in FIG. 5 may be obtained by cutting the substrate structure 100W illustrated in FIGS. 1 to 4.

Referring to FIG. 5, the semiconductor device 100, according to some example embodiments, may include a device region DA and a scribe lane SL′ remaining around the device region DA after a cutting process. The residual scribe lane SL′ may be provided as or along an edge region of the semiconductor device 100.

In some example embodiments, the residual scribe lane SL′ may include a first residual scribe lane portion SL1′ on the first side S1 and a second residual scribe lane portion SL2′ on the second side S2. Here, a width da of the first residual scribe lane SL1′ may be substantially the same as a width db of the second residual scribe lane portion SL2′. The cutting width is a width of the scribe lane SL portion lost during the cutting process and may be located to overlap the center lines C1 and C2, and in some cutting processes, the cutting width may be a relatively smaller width of 10 μm (or about 10 μm) or less, or 5 μm (or about 5 μm) or less.

In some example embodiments, the first and second residual metal patterns 160a and 160b may remain on the first and second residual scribe lane portions (SL1′, SL2′) from the first metal patterns 160A, respectively, after the cutting process. The first and second residual metal patterns 160a and 160b may have different widths due to the offset arrangement of the first metal patterns 160A. As illustrated in FIG. 5, a width w2 of the second residual metal patterns 160b may be greater than a width w1 of the first residual metal patterns 160a.

The residual scribe lane SL′ includes residual scribe lane portions on the third side S3 and the fourth side S4, respectively, and may have residual metal patterns similar to the first and second residual metal patterns 160a and 160b. If the second metal patterns 160B are also arranged in an offset manner, the residual metal patterns on the third side S3 and the fourth side S4 may have different widths similar to the first and second residual metal patterns 160a and 160b. However, if the second metal patterns 160B are not arranged in an offset manner, the residual metal patterns on the third side S3 and the fourth side S2 may have the same or similar width.

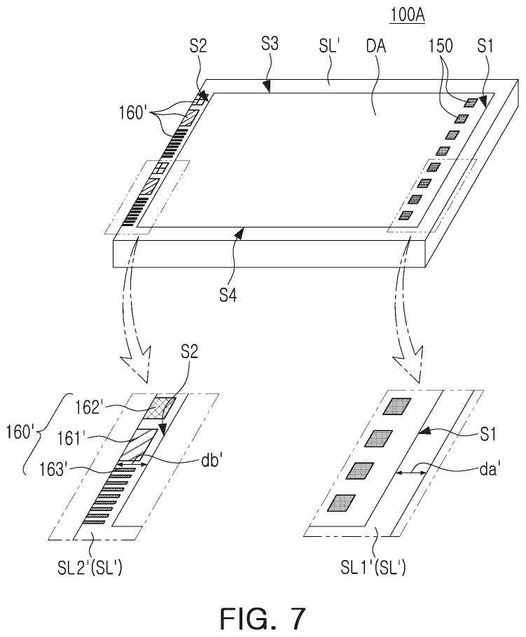

FIG. 6 is a cross-sectional side view illustrating a semiconductor package including the semiconductor devices of FIG. 5.

Referring to FIG. 6, a semiconductor package 200 according to some example embodiments may include a substrate 210, a plurality of stacked semiconductor devices 100, and a molded portion 280.

The substrate 210 may have a structure in which an insulating film and an interconnection layer are alternately stacked. For example, the substrate 210 may be a printed circuit board (PCB). The substrate 210 may include a plurality of substrate pads 220 arranged on one side of the upper surface. The plurality of substrate pads 220 may be arranged in a second direction D2 so as to be spaced apart from each other.

External terminals 290 may be provided on a lower surface of the substrate 210.

Each of the external terminals 290 may include a conductive material. For example, the external terminals 290 may include, but are not limited to, copper (Cu), aluminum (Al), silver (Ag), tin (Sn), gold (Au), nickel (Ni), lead (Pb), titanium (Ti), or alloys thereof. Each of the external terminals 290 is illustrated as having a ball shape, but example embodiments of the inventive concepts are not limited thereto. Each of the external terminals 290 may have various other shapes, such as a land, a ball, a pin, a pillar, etc. The number, spacing, arrangement, etc. of the external terminals 290 are not limited to those illustrated, and may vary depending on the application and/or design. Each of the external terminals 290 may be a solder bump including a low-melting-point metal, such as tin (Sn) and a tin (Sn) alloy, but is not limited thereto.

The semiconductor devices 100 may be the semiconductor devices described above with reference to FIG. 5. The semiconductor devices 100 may be arranged on the substrate 210 in an offset stack structure. For example, the semiconductor devices 100 may be stacked while being offset in the second direction D2, which may have an upwardly inclined step shape. As illustrated in FIG. 6, the semiconductor devices 100 may be stacked so that regions in which the bonding pads are arranged do not overlap. The semiconductor devices 100 may be bonded to each other by an adhesive layer 260. The bonding pads 150 of the semiconductor devices 100 may be connected to the substrate pads 220 by wires W, respectively. The wires W may be bonded by a stitch bonding method or a ball bonding method. The molded portion 280 may be formed on the substrate 210 to cover the stack of semiconductor devices 100 and the wires W.

In some example embodiments, the semiconductor devices 100 may be a volatile memory device or a non-volatile memory device. For example, the semiconductor devices 100 may be DRAM chips, but example embodiments of the inventive concepts are not limited thereto.

FIG. 7 is a perspective view illustrating a semiconductor device according to some example embodiments of the inventive concepts.

Referring to FIG. 7, a semiconductor device 100A according to some example embodiments may be understood as having a structure same as or similar to that of the semiconductor device 100 illustrated in FIG. 5. In the semiconductor device 100A, a residual metal pattern may be absent in the scribe lane portion remaining on the first side. The semiconductor device 100A may be same as or similar in some respects to the substrate structure 100W illustrated in FIGS. 1 to 4 and the semiconductor device 100 illustrated in FIG. 5, and therefore may be best understood with reference thereto where like numerals indicate like elements not described again in detail.

The semiconductor device 100A, according to some example embodiments, may include the device region DA and the scribe lane SL′ remaining around the device region DA, similar to the semiconductor device 100 discussed above. The residual scribe lane SL′ may include a first residual scribe lane portion SL1′ on the first side S1 and a second residual scribe lane portion SL2′ on the second side S2. A width da′ of the first residual scribe lane SL1′ may be substantially equal to a width db′ of the second residual scribe lane portion SL2′.

However, in some example embodiments, while metal pattern is absent on the first residual scribe lane portion SL1′ on the first side S1, and residual metal patterns 160′ from the first metal patterns 160A may remain on the second residual scribe lane portion SL2′ on the second side S2.

For example, when a portion lost due to the cutting width is relatively larger, metal pattern may not remain on the first residual scribe lane portion SL1′ on the first side S1, but residual metal patterns 160′ may remain on the second residual scribe lane portion SL2′ on the second side S2. As a result, the widths da′ and db′ of the first and second residual scribe lane portions SL1 and SL2′ may be relatively smaller than the widths da and db in FIG. 5.

As illustrated, metal pattern may not remain on the first residual scribe lane portion SL1′ on the first side S1. However, in some example embodiments, since the widths of the first metal patterns 160A are different, metal patterns (e.g., test pads) having relatively large widths may partially remain.

FIGS. 8A to 8D are cross-sectional views illustrating processes of a method of manufacturing a semiconductor device according to some example embodiments of the inventive concepts. FIGS. 9A and 9B are perspective views illustrating processes of a method of manufacturing a semiconductor device according to some example embodiments of the inventive concepts.

Referring to FIGS. 8A and 9A, a protective sheet 400 may be attached on the upper surface 110A of the substrate structure 100W. FIG. 8A is a cross-section of the substrate structure 100W of FIG. 9A taken along line II-II′, illustrating a state in which a protective sheet 400 is completely attached to the substrate structure 100W.

The substrate structure 100W may be positioned so that the surface to which the protective sheet 400 is attached faces a support, such as a chuck table 310 (e.g., FIG. 8B). The protective sheet 400 may protect the device regions DA and the interconnection structure 130, while the cutting process of the substrate structure 100W is performed. For example, the protective sheet 400 may be a polyvinyl chloride (PVC) polymer sheet and may be attached to the interconnection structure 130 by an acrylic resin adhesive. For example, the acrylic resin adhesive may be applied to a thickness of 2 μm (or about 2 μm) to 10 μm (or about 10 μm). For example, the protective sheet 400 may have a thickness of 60 μm (or about 60 μm) to 200 μm (or about 200 μm). In some example embodiments, the protective sheet 400 may have a circular shape having a diameter substantially the same as or similar to the diameter of the substrate structure 100W.

Next, referring to FIGS. 8B and 9B, a laser LA may be irradiated to form modified portions MP within the semiconductor substrate 110.

After attaching the protective sheet 400 on the substrate structure 100W, the lower surface 100B of the substrate structure 100W, for example, the lower surface 110B of the semiconductor substrate 110, may be irradiated with the laser LA along the scribe lane SL. The laser LA has a wavelength transparent to the semiconductor substrate 110, and the irradiation of the laser LA may be controlled to form a focusing point in a specific region or location inside the semiconductor substrate 110.

As shown in FIG. 9B, by irradiating the laser LA at constant intervals along the center line C of the scribe lane SL, the modified portion MP may be formed at a constant depth inside the semiconductor substrate 110. The formation of the modified portion MP may be performed using a laser irradiation device 300.

The laser irradiation device 300 may include a chuck table 310 supporting or securing the semiconductor substrate 110, a laser irradiation unit 320 irradiating the semiconductor substrate 110 disposed on the chuck table 310 with a laser RA, and an imaging unit 330 capturing an image of the semiconductor substrate 110 disposed on the chuck table 310. The chuck table 310 may be configured to support or secure the semiconductor substrate 110 by suction with vacuum pressure and move the semiconductor substrate 110 in a row direction (e.g., an X-direction) and a column direction (e.g., Y-direction).

The laser irradiation unit 320 may be configured to irradiate a pulse laser from a condenser 324 mounted on a front end of a substantially horizontally arranged cylindrical housing 322. In addition, while irradiating the semiconductor substrate 110 with a pulse laser having a wavelength transparent to the semiconductor substrate 110 from the condenser 324, the chuck table 310 and the condenser 324 may move relative to each other at an appropriate speed.

The imaging unit 330 also mounted on the housing 322 constituting the laser irradiation unit 320 may be a general CCD imaging device capturing images using visible light. In some example embodiments, the imaging unit 330 may include an infrared irradiation unit irradiating the semiconductor substrate 110 with infrared light, an optical system capturing infrared light irradiated by the infrared irradiation unit, and an infrared CCD imaging device outputting an electrical signal corresponding to the infrared light captured by the optical system.

The laser irradiation unit 320 may be aligned at a laser irradiation position and then irradiate the laser LA. By focusing the laser LA on the inside or interior of the semiconductor substrate through a lower surface of the semiconductor substrate, the modified portion MP may be formed. The modified portion MP may be obtained by melting a portion of the semiconductor substrate 110 by focusing the laser LA. The modified portion MP may function as a crack site in which a crack may occur due to an external physical impact (e.g., cooling and/or expansion) in a subsequent process. The modified portion MP may be relatively closer to the upper surface 110A than the lower surface 110B of the semiconductor substrate 110.

Next, referring to FIG. 8C, the lower surface 110B of the semiconductor substrate 110 may be polished to thin the substrate structure 100W.

By polishing the lower surface 110B of the semiconductor substrate 110 using a polishing device, a thickness of the semiconductor substrate 110 may be reduced from a first thickness T1 to a second thickness T2. This polishing process may be performed, while the substrate structure 100W is supported on the chuck table 410. The polished semiconductor substrate 110 may have the second thickness T2 less than the first thickness T1 (see FIG. 8A). For example, the first thickness T1 may be in a range of 0.1 mm (or about 0.1 mm) to 1 mm (or about 1 mm), and the second thickness T2 may be in a range of 20 μm (or about 20 μm) to 100 μm (or about 100 μm). Since the modified portion MP is located closer to the upper surface 110A of the semiconductor substrate 110, it may remain in the semiconductor substrate 110 even after the polishing process.

Next, referring to FIG. 8D, the substrate structure 100W may be separated into a plurality of semiconductor devices 100.

Using the pre-formed modified portion MP, the substrate structure 100W may be separated along the scribe lane SL, thereby forming a plurality of semiconductor devices 100 having the device region DA, as shown in FIG. 5. After thinning the substrate structure 100W, a tape 500 may be attached to the lower surface 110B of the semiconductor substrate 110, the substrate structure 100W may be separated from the chuck table 310, and the protective sheet 400 may be removed. Next, the tape 500 may be horizontally expanded to separate the substrate structure 100W into a plurality of semiconductor devices 100. During this expansion process, a crack for cutting may occur, starting from the modified portion MP, so that the substrate structure 100W may be separated into a plurality of semiconductor devices 100.

In some example embodiments, a process of cooling the substrate structure 100W may be further performed before expanding the tape 500. The modified portion MP of the substrate structure 100W may vertically propagate by a thermal shock occurring during a process of recovering to room temperature, so that the process of separation into a plurality of semiconductor devices 100 by the expansion of the tape 500 may be performed with relative ease. Next, since the separated semiconductor devices 100 are in a state in which the tape 500 is horizontally expanded, a space may be secured between the semiconductor devices 100, and the semiconductor devices 100 may be picked up with relative ease.

In this manner, the finally separated semiconductor devices 100 may have an edge region (residual scribe lane portion) in which the offset arranged metal patterns remain in different shapes, as described above with reference to FIGS. 5 and 7.

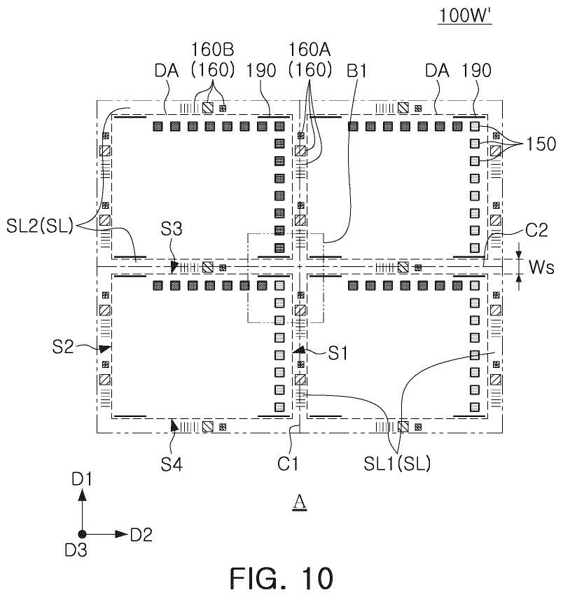

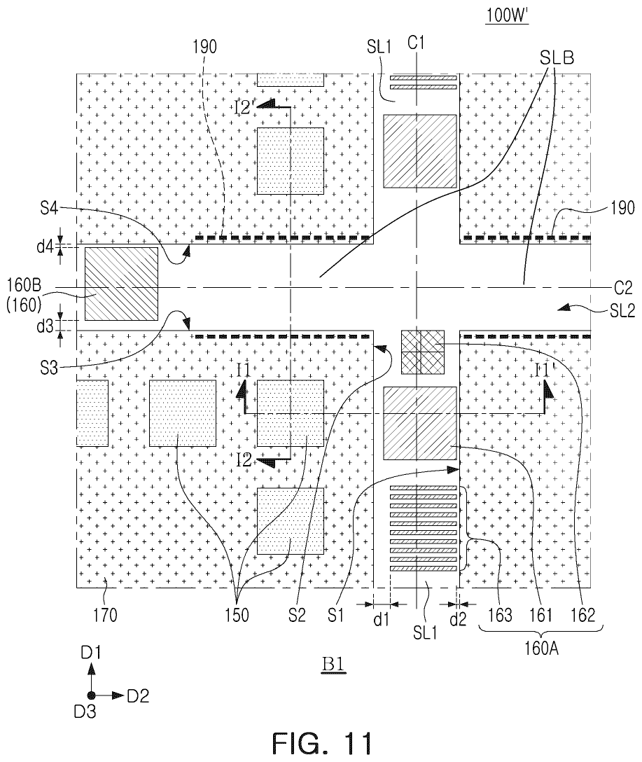

FIG. 10 is a plan view illustrating a portion of a substrate structure for a plurality of semiconductor devices. FIG. 11 is a partially enlarged view illustrating portion B1 of FIG. 10. FIGS. 12A and 12B are side cross-sectional views of a wafer portion of FIG. 11 taken along lines I1-I1′ and I2-I2′.

Referring to FIGS. 10 and 11, a substrate structure 100W′ may be same as or similar to the substrate structure 100W illustrated in FIGS. 1 to 4, and therefore may be best understood with reference thereto where like numerals indicate like elements not described again in detail. In the substrate structure 100W′ the bonding pads 150 are additionally arranged in the region adjacent to the first side S1 and in the region adjacent to the third side S3 in each of the plurality of device regions DA, the second metal patterns 160B are arranged in an offset manner in the second scribe lane SL2, and a moat structure 190 is formed around the region of the second scribe lane SL2 in which the second metal patterns 160B are absent.

Each of the device regions DA may include the bonding pads 150 arranged in a region adjacent to the first side S1 and in a region adjacent to the third side S3. In addition, the first metal patterns 160A are arranged offset in the first scribe lane SL1. In some example embodiments, the second metal patterns 160B may also be arranged offset in the second scribe lane SL2.

Referring to FIGS. 11 and 12A, in each of the first scribe lanes SL1, the first metal patterns 160A may be arranged to be offset closer to the second side S2 than to the first side S1 from the first center line C1 of each of the first scribe lanes SL1. By the offset arrangement, the first metal patterns 160A may be arranged so that the distance (e.g., d1) from the first side S1 is greater than the distance (e.g., d2) from the second side S2.

In some example embodiments, each of the plurality of device regions DA has the third side S3 and the fourth side S4 located opposite to each other in the first direction D1, and the plurality of device regions DA may be arranged such that the third side S3 and the fourth side S4 face each other with the second scribe lanes SL2 interposed therebetween. In the region adjacent to the third side S3, the bonding pads 150 are additionally arranged, while the region adjacent to the fourth side S4 is provided as a pad-free region in which no bonding pads are arranged.

In each of the second scribe lanes SL2, the second metal patterns 160B may be arranged to be offset closer to the fourth side S4 than to the third side S3 from the second center line C2 of each of the second scribe lanes SL2. By the offset arrangement, the second metal patterns 160B may be arranged so that the distance (e.g., d3) from the third side S3 is greater than the distance (e.g., d4) from the fourth side S4.

Referring to FIGS. 11 and 12B, the moat structure 190 may be formed around the region of the second scribe lane SL2 in which the second metal patterns 160B are not arranged. The substrate structure 100W′ according to some example embodiments may include the passivation layer 170 arranged on regions (or portions or sections) of the interconnection structure 130 on a plurality of device regions DA, and at least a portion of the second scribe lane SL2 may include a bare scribe lane region SLB in which the second metal patterns 160B are not arranged. In some example embodiments, a trench T may be formed in the interconnection structure 130 between the bare scribe lane region SLB and the plurality of device regions DA, and the passivation layer 170 may extend into (or otherwise occupy) the trench T to form the moat structure 190. The moat structure 190 may limit a transverse crack from occurring during a cutting process and suppress peeling.

However, when the metal patterns 160, such as the test pad 161, are arranged in the scribe lane, the test pad 161 may be connected to the device region DA by the interconnection layer 135, the moat structure 190 may be omitted. Thus, when the metal patterns 160, such as test pad 161, are located in the scribe lane SL (see FIG. 12A), the metal patterns 160 may be arranged relatively closer to the pad-free region in which the bonding pads 150 are not present, as in some example embodiments, thereby effectively limiting the defects of the bonding pads 150 due to peeling.

According to some example embodiments described above, depending on the arrangement of the bonding pads, by arranging the bonding pads relatively closer to the device region on one side from the central axis of the scribe lane, the defects of the bonding pads due to cracks occurring during cutting may be reduced, and the reliability of the semiconductor device may be improved.

While several embodiments have been provided in the present disclosure, it should be understood that the disclosed systems and methods might be embodied in many other specific forms without departing from the spirit or scope of the present disclosure. The present example embodiments are to be considered as illustrative and not restrictive, and the intention is not to be limited to the details given herein. For example, the various elements or components may be combined or integrated in another system or certain features may be omitted, or not implemented.

What is claimed is:

1. A method of manufacturing a semiconductor device, the method comprising:
irradiating a laser along a center line of a scribe lane of a substrate structure, wherein
the substrate structure includes a plurality of device regions that are separated by the scribe lane and a plurality of metal patterns arranged on the scribe lane,
the substrate structure includes a semiconductor substrate having an upper surface on which circuit devices are formed, and an interconnection structure disposed on the upper surface of the semiconductor substrate and electrically connected to the circuit devices, and
irradiating the laser along the center line of the scribe lane forms modified portions in the semiconductor substrate;
polishing a lower surface of the semiconductor substrate to reduce a thickness the substrate structure; and
separating the substrate structure into the plurality of device regions to form a plurality of semiconductor devices, wherein
each device region of the plurality of device regions includes bonding pads arranged along a first side of the device region,
in each device region of the plurality of device regions, bonding pads are absent on a region adjacent to a second side of the device region opposite to the first side,
the plurality of device regions are arranged such that the first side and the second side of each device region face each other and the scribe lane is therebetween, and
the plurality of metal patterns are closer to the second side than to the first side in the scribe lane.

2. The method of claim 1, wherein the plurality of metal patterns include at least one of a test pad and an alignment key.

3. The method of claim 2, wherein
the interconnection structure includes a plurality of interconnection layers connected to the circuit devices, and
the plurality of interconnection layers include interconnection layers connected to the test pad.

4. The method of claim 1, wherein at least one metal pattern of the plurality of metal patterns is offset by at least 10% of a width thereof from the center line of the scribe lane.

5. The method of claim 4, wherein
the scribe lane has a width of 40 μm to 100 μm, and
the plurality of metal patterns have a width of 20 μm to 60 μm.

6. The method of claim 1, wherein the plurality of metal patterns are arranged such that a distance from the first side is at least 5 μm more than a distance from the second side.

7. The method of claim 1, wherein separating the substrate structure into the plurality of device regions to form the plurality of semiconductor devices includes:
attaching a tape to the lower surface of the semiconductor substrate after thinning the substrate structure,
cooling the substrate structure attached to the tape, and
expanding the tape to separate the plurality of semiconductor devices from the substrate structure.

8. The method of claim 1, wherein, after separating, each of the plurality of semiconductor devices includes a portion of the scribe lane remaining around each of the plurality of device regions, and
a residual scribe lane portion along the first side has a same width as a width of a residual scribe lane portion along the second side.

9. The method of claim 8, wherein
after separating, each of the plurality of semiconductor devices further includes first residual metal patterns remaining from the plurality of metal patterns on the residual scribe lane portion at the first side and second residual metal patterns remaining from the plurality of metal patterns on the residual scribe lane portion at the second side, and
a width of the second residual metal patterns is more than a width of the first residual metal patterns.

10. The method of claim 8, wherein, after separating, metal patterns are absent on the residual scribe lane portion at the first side, and
the residual scribe lane portion at the second side includes residual metal patterns from the metal patterns.

11. The method of claim 1, wherein the substrate structure further includes a passivation layer on portions of the interconnection structure on the plurality of device regions.

12. The method of claim 11, wherein
the scribe lane includes a bare scribe lane region in which the plurality of metal patterns are absent,
the interconnection structure includes a trench between the bare scribe lane region and the plurality of device regions, and
the passivation layer extends into the trench.

13. A method of manufacturing a semiconductor device, the method comprising:
irradiating a laser along center lines of a plurality of first scribe lanes and a plurality of second scribe lanes of a substrate structure, wherein the substrate structure includes
the plurality of first scribe lanes extending in a first direction and spaced apart from each other in a second direction that intersects the first direction,
the plurality of second scribe lanes extending in the second direction and spaced apart from each other in the first direction,
a plurality of device regions defined by the plurality of first scribe lanes and the plurality of second scribe lanes,
a semiconductor substrate having an upper surface including circuit devices, and an interconnection structure on the upper surface of the semiconductor substrate and electrically connected to the circuit devices, and
irradiating the laser along the center lines of the plurality of first scribe lanes and the plurality of second scribe lanes forms modified portions in the semiconductor substrate;
polishing a lower surface of the semiconductor substrate to reduce a thickness of the substrate structure; and
separating the substrate structure into the plurality of device regions to form a plurality of semiconductor devices, wherein
each device region of the plurality of device regions has a first side and a second side opposite to each other in the second direction, and in the substrate structure, the plurality of device regions are arranged such that the first side and the second side face each other and a first scribe lane of the plurality of first scribe lanes is therebetween,
each device region of the plurality of device regions includes first bonding pads arranged along the first side,
in each device region of the plurality of device regions, bonding pads are absent on a region adjacent to the second side, and
the substrate structure further includes first metal patterns offset from the center line of each of the plurality of first scribe lanes, the first metal patterns being closer to the second side than the first side.

14. The method of claim 13, wherein the first metal patterns are offset by at least 10% of a width thereof from the center line of each of the plurality of first scribe lanes.

15. The method of claim 13, wherein
each of the plurality of device regions has a third side and a fourth side located opposite to each other in the first direction,
in the substrate structure, the plurality of device regions are arranged such that the third side and the fourth side face each other and a second scribe lane is therebetween, and
each device region of the plurality of device regions includes second bonding pads arranged along the third side, and, in each device region, bonding pads are absent in a region adjacent to the fourth side.

16. The method of claim 15, wherein the substrate structure further includes second metal patterns offset from the center line of each of the plurality of second scribe lanes, the second metal patterns being closer to the fourth side than to the third side.

17. The method of claim 13, wherein
after separating, each of the plurality of semiconductor devices includes a portion of a scribe lane remaining around each of the plurality of device regions, first residual metal patterns remaining from the first metal patterns on a residual scribe lane portion at the first side, and second residual metal patterns remaining from the first metal patterns on a residual scribe lane portion at the second side, and
a width of the second residual metal patterns is more than a width of the first residual metal patterns.

18. The method of claim 13, wherein, after separating, each of the plurality of semiconductor devices further includes a portion of a scribe lane remaining around each of the plurality of device regions, metal pattern is absent on a residual scribe lane portion adjacent the first side, and residual metal patterns from the first metal patterns remain on a residual scribe lane portion adjacent the second side.

19. The method of claim 13, wherein at least one of the first metal patterns includes a test pad, and the interconnection structure includes a plurality of interconnection layers connected to the circuit devices, and at least one interconnection layer of the plurality of interconnection layers is connected to the test pad.

20. A method of manufacturing a semiconductor device, the method comprising:
cutting a substrate structure along a scribe lane to separate a plurality of semiconductor devices from the substrate structure, the substrate structure including a plurality of device regions and the scribe lane separating the plurality of device regions, wherein
each of the plurality of device regions includes a first side and a second side opposite the first side,
each of the plurality of device regions includes bonding pads arranged along the first side, and bonding pads are absent on a region adjacent to the second side,
the plurality of device regions are arranged such that the first side and the second side of adjacent device regions face each other and the scribe lane is therebetween, and
the substrate structure further includes metal patterns arranged closer to the second side than to the first side in the scribe lane.
